(19) United States
(12) Patent Application Publication
(10) Pub. No.: US 2023/0062105 A1
(43) Pub. Date: Mar. 2, 2023

(54) FILM FORMING METHOD AND FILM FORMING APPARATUS

(71) Applicant: Tokyo Electron Limited, Tokyo (JP)

(72) Inventors: Makoto WADA, Nirasaki City (JP); Yutaka FUJINO, Nirasaki City (JP); Hiroyuki IKUTA, Nirasaki City (JP); Hideki YUASA, Nirasaki City (JP); Hirokazu UEDA, Osaka (JP)

(21) Appl. No.: 17/820,962

(22) Filed: Aug. 19, 2022

(30) Foreign Application Priority Data
Aug. 30, 2021 (JP) 2021-139585

(51) Int. Cl. C23C 16/44; C23C 16/511; C23C 16/34; H01J 37/32

(52) U.S. Cl. CPC C23C 16/4405; C23C 16/4404; C23C 16/511; C23C 16/345; H01J 37/32862; H01J 37/32201; H01J 37/3244; H01J 2237/3321

(57) ABSTRACT

A film forming method includes repeatedly performing: forming a film on one substrate or consecutively on a plurality of substrates by supplying a film formation gas into a processing container while heating the substrate on a stage; cleaning an interior of the processing container by a fluorine-containing gas by setting a temperature of the stage to a first temperature at which a vapor pressure of an aluminum fluoride becomes lower than a control pressure in the processing container in a state in which the substrate is unloaded from the processing container; and performing a precoating continuously to the cleaning the interior of the processing container such that a precoat film is formed on at least a surface of the stage by setting the temperature of the stage to a second temperature at which the vapor pressure of the aluminum fluoride becomes lower than the control pressure in the processing container.

### CROSS-REFERENCE TO RELATED APPLICATION

This application is based upon and claims the benefit of priority from Japanese Patent Application No. 2021-139585, filed on Aug. 30, 2021, the entire contents of which are incorporated herein by reference.

### TECHNICAL FIELD

The present disclosure relates to a film forming method and a film forming apparatus.

### BACKGROUND

Patent Document 1 discloses a technique of cleaning, after performing a film forming process or the like in a processing container of a microwave plasma processing apparatus, an interior of the processing container by using NF₃ gas excited by plasma.

### PRIOR ART DOCUMENT

### Patent Document

Patent Document 1: Japanese Patent Laid-Open Publication No. 2019-216150

### SUMMARY

According to one embodiment of the present disclosure, there is provided a film forming method of forming a film on a substrate by using a film forming apparatus including a processing container and an aluminum-containing stage on which the substrate is placed in the processing container. The film forming method includes: forming the film on one substrate or consecutively on a plurality of substrates by supplying a film formation gas into the processing container while heating the substrate on the stage; cleaning an interior of the processing container by a fluorine-containing gas by setting a temperature of the stage to a first temperature at which a vapor pressure of an aluminum fluoride becomes lower than a control pressure in the processing container in a state in which the substrate is unloaded from the processing container; and performing a precoating continuously to the cleaning the interior of the processing container such that a precoat film is formed on at least a surface of the stage by setting the temperature of the stage to a second temperature at which the vapor pressure of the aluminum fluoride becomes lower than the control pressure in the processing container, wherein the forming the film, the cleaning the interior of the processing container, and the performing the precoating are repeatedly performed.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating an example of a film forming apparatus for executing a film forming method according to an embodiment.

FIG. 2 is a cross-sectional view illustrating a cross section of the film forming apparatus of FIG. 1 taken along line A-A.

FIG. 3 is a flowchart illustrating a film forming method according to an embodiment.

FIG. 4 is a schematic view for explaining a state inside a processing container after a film forming process.

FIGS. 5A to 5C are views for explaining generation of AlFₓ during a cleaning process and an effect of sublimation of the generated AlFₓ.

FIG. 6 is a diagram showing a relationship between a theoretical vapor pressure curve of AlF₃ and a control pressure in a general processing container.

FIG. 7 is a view illustrating a state in which AlFₓ on a surface of a stage is shielded by a precoating process.

FIG. 8 is a diagram for explaining a temperature change of the stage in the film forming method according to the embodiment.

FIG. 9 is a schematic view for explaining a method of measuring an amount of AlF₃ sublimated from the stage.

FIG. 10 is a diagram showing a relationship between a theoretical vapor pressure curve of AlF₃ and a control pressure in a processing container in a film forming method according to another embodiment.

FIG. 11 is a diagram for explaining a case where a pressure increase control is performed even during a temperature increase before the film forming process, during a substrate transfer in the film forming process, and during a temperature decrease after the film forming process in the film forming method according to another embodiment.

FIG. 12 is a flowchart illustrating a film forming method according to still another embodiment.

FIG. 13 is a view illustrating a state in which a first precoat film and a second precoat film are formed after a second precoating process is performed in the film forming method according to still another embodiment.

FIG. 14 is a view illustrating a state in which an intermediate precoat film is formed between the first precoat film and the second precoat film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments will be described in detail with reference to the accompanying drawings.

### <Film Forming Apparatus>

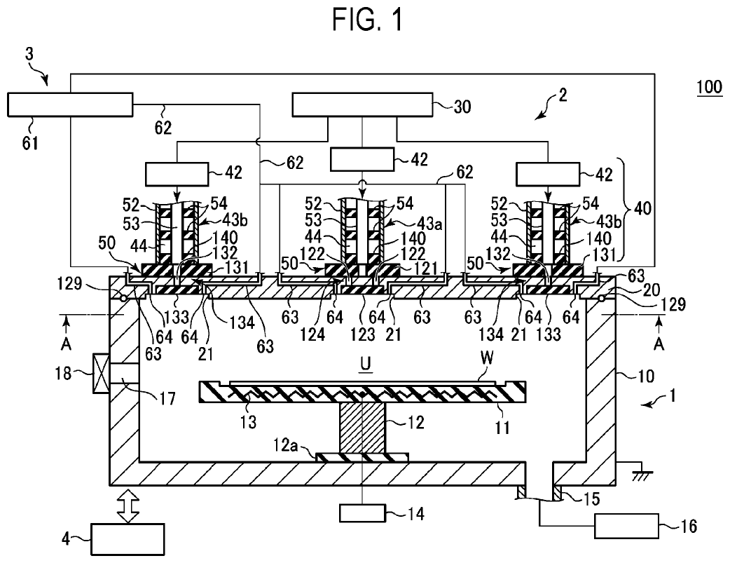

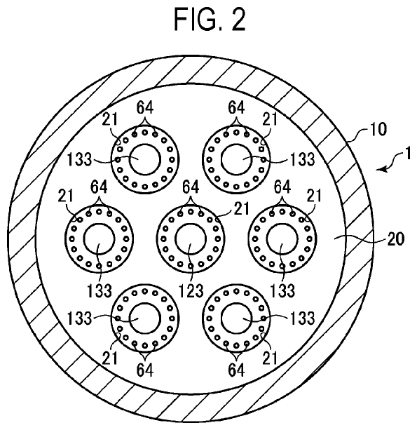

FIG. 1 is a cross-sectional view illustrating an example of a film forming apparatus for executing a film forming method according to an embodiment, and FIG. 2 is a cross-sectional view illustrating a cross section of the film forming apparatus of FIG. 1 taken along line A-A.

A film forming apparatus 100 is configured as a plasma processing apparatus that performs plasma processing by using microwave plasma.

The film forming apparatus 100 includes a processing container (chamber) 1 that accommodates a substrate W. The film forming apparatus 100 performs a film forming process on the substrate W by using surface wave plasma, which is formed in a vicinity of an inner wall surface of a ceiling wall in the processing container 1 by microwaves radiated in the processing container 1. A film formed by the film forming process is not particularly limited, and an example thereof includes a Si-containing film such as a silicon nitride film (SiN film). Although a semiconductor wafer is exemplified as the substrate W, the substrate W is not limited to the semiconductor wafer and may be another substrate such as an FPD substrate or a ceramic substrate.

The film forming apparatus 100 includes a plasma source 2, a gas supply mechanism 3, and a controller 4 in addition to the processing container 1.

The processing container 1 includes a substantially cylindrical container main body 10 having an open upper portion and a ceiling wall 20 that closes the upper opening of the container main body 10, so that a plasma processing space is formed inside the processing container 1. The container main body 10 is made of a metallic material such as aluminum or stainless steel and is grounded. The ceiling wall 20 is made of a metallic material such as aluminum or stainless steel and has a disk shape. A seal ring 129 is interposed on a contact surface between the container main body 10 and the ceiling wall 20, whereby an interior of the processing container 1 is airtightly sealed.

A stage 11 on which the substrate W is placed is horizontally provided in the processing container 1, and is supported by a cylindrical support 12 erected at a center of a bottom of the processing container 1. The stage 11 is made of an aluminum (Al)-containing material, for example, an aluminum nitride (AlN), which is insulating ceramic. In addition, the material constituting the stage 11 may be alumina (Al₂O₃), which is also Al-containing insulating ceramic. The support 12 may be made of metal or ceramic. When the support 12 is made of metal, an insulating member 12a is interposed between the support 12 and the bottom of the processing container 1. A heater 13 is provided in the stage 11, and a heater power supply 14 is connected to the heater 13. By supplying power from the heater power supply 14 to the heater 13, the stage 11 is heated to an arbitrary temperature up to, for example, 700 degrees C. The stage 11 is provided with three lifting pins (not illustrated) for raising and lowering the substrate W, so that the substrate W is delivered in a state in which the lifting pins protrude from a surface of the stage 11. The stage 11 may be further provided with an electrostatic chuck for electrostatically attracting the substrate W, a gas flow path for supplying a heat transfer gas to a rear surface of the substrate W, or the like. In addition, the stage 11 may be provided with an electrode, and a radio-frequency bias for drawing ions in plasma may be applied to the electrode.

An exhaust pipe 15 is connected to the bottom of the processing container 1, and an exhaust device 16 including a vacuum pump is connected to the exhaust pipe 15. When the exhaust device 16 is operated, the interior of the processing container 1 is evacuated, whereby the interior of the processing container 1 is quickly depressurized to a predetermined degree of vacuum. A side wall of the processing container 1 is provided with a load/unload port 17 for loading and unloading the substrate W and a gate valve 18 for opening and closing the load/unload port 17.

The plasma source 2 is for generating microwaves and radiating the generated microwaves into the processing container 1 to generate plasma, and includes a microwave output 30, a microwave transmitter 40, and microwave radiators 50.

The microwave output 30 includes a microwave power supply, a microwave oscillator that oscillates microwaves, an amplifier that amplifies the oscillated microwaves, and a distributor that distributes the amplified microwaves into plural ones. Thus, the microwaves distributed into plural ones are output.

The microwaves output from the microwave output 30 are radiated into the processing container 1 via the microwave transmitter 40 and the microwave radiators 50. In addition, a gas is supplied into the processing container 1 as described later, and the supplied gas is excited by the introduced microwaves to form surface wave plasma.

The microwave transmitter 40 transmits the microwaves output from the microwave output 30. The microwave transmitter 40 includes a plurality of amplifiers 42, a central microwave introducer 43a disposed at a center of the ceiling wall 20, and six peripheral microwave introducers 43b disposed at equal intervals in a peripheral portion of the ceiling wall 20. The plurality of amplifiers 42 amplifies the microwaves distributed by the distributor of the microwave output 30, and are provided correspondingly to the central microwave introducer 43a and the six peripheral microwave introducers 43b, respectively. The central microwave introducer 43a and the six peripheral microwave introducers 43b have a function of introducing the microwaves output from the amplifiers 42, which are provided correspondingly thereto, respectively, into the microwave radiators 50, and have an impedance-matching function.

Each of the central microwave introducer 43a and the peripheral microwave introducers 43b has a configuration in which a cylindrical outer conductor 52 and a rod-shaped inner conductor 53 provided at a center thereof are coaxially disposed. A space between the outer conductor 52 and the inner conductor 53 forms a microwave transmission path 44, which is fed with microwave power so that the microwaves propagate toward the microwave radiator 50 therethrough.

Each of the central microwave introducer 43a and the peripheral microwave introducers 43b is provided with a pair of slugs 54 and an impedance adjuster 140 located at a tip portion thereof. By moving the slugs 54, an impedance of a load (plasma) in the processing container 1 is matched with a characteristic impedance of the microwave power supply in the microwave output 30. The impedance adjuster 140 is made of a dielectric material, and adjusts an impedance of the microwave transmission path 44 by a relative dielectric constant of the impedance adjuster 140.

Each of the microwave radiators 50 includes a slow-wave member 121 or 131, a slot antenna 124 or 134 having a slot 122 or 132, and a dielectric member 123 or 133. The slow-wave members 121 and 131 are provided at positions corresponding to the central microwave introducer 43a on a top surface of the ceiling wall 20 and at positions corresponding to the peripheral microwave introducers 43b on the top surface of the ceiling wall 20, respectively. In addition, the dielectric members 123 and 133 are provided inside the ceiling wall 20 at positions corresponding to the central microwave introducer 43a and at the peripheral microwave introducers 43b, respectively. Slots 122 and 132 are provided in a portion of the ceiling wall 20 between the slow-wave member 121 and the dielectric member 123, and portions of the ceiling wall 20 between the slow-wave members 131 and the dielectric members 133, respectively, and the portions where the slots are formed become the slot antennas 124 and 134, respectively.

Each of the slow-wave members 121 and 131 has a disk shape, is disposed to surround a tip portion of the inner conductor 53. Each of the slow-wave members 121 and 131 has a dielectric constant greater than that of vacuum, and is made of, for example, quartz, ceramic, a fluorine-based resin such as polytetrafluoroethylene, or a polyimide-based resin. The slow-wave members 121 and 131 have a function of shortening a wavelength of the microwaves than that in vacuum to reduce a size of the antennas. The slow-wave members 121 and 131 can adjust a phase of the microwaves based on a thickness thereof, and the thickness of the slow-wave members 121 and 131 is adjusted such that the slot antennas 124 and 134 become “antinodes” of standing waves to minimize reflection and maximize radiant energy of the slot antennas 124 and 134.

Like the slow-wave members 121 and 131, the dielectric members 123 and 133 are made of, for example, quartz, ceramic such as alumina (Al₂O₃), a fluorine-based resin such as polytetrafluoroethylene, or a polyimide-based resin. The dielectric members 123 and 133 are inserted into spaces formed inside the ceiling wall 20, and concave windows 21 are formed on a bottom surface of the ceiling wall 20 at positions corresponding to the dielectric members 123 and 133. Therefore, the dielectric members 123 and 133 are exposed in the processing container 1 and function as dielectric windows for supplying the microwaves to a plasma generation space U.

The number of peripheral microwave introducers 43b and dielectric members 133 is not limited to six, and may be two or more, specifically, three or more.

As will be described later, the gas supply mechanism 3 supplies a film formation gas, a cleaning gas, and a gas for plasma processing after cleaning into the processing container 1. The gas supply mechanism 3 includes a gas supply 61, a gas pipe 62 via which the gas from the gas supply 61 is supplied, a gas flow path 63 provided in the ceiling wall 20, and gas discharge ports 64 from which the gas from the gas flow path 63 is discharged. A plurality of gas discharge ports 64 is provided in each of the windows 21 of the ceiling wall 20 to surround each of the dielectric members 123 and 133 (see FIG. 2).

The gas supply mechanism 3 is not limited to discharge the gas from the ceiling wall 20 as in this example.

The controller 4 controls operations or processings of respective component of the film forming apparatus 100, for example, a gas supply of the gas supply mechanism 3, a frequency or output of the microwaves of the plasma source 2, an exhaust by the exhaust device 16, and the like. The controller 4 is typically a computer, and includes a main controller, an input device, an output device, a display device, and a storage device. The main controller includes a central processing unit (CPU), a RAM, and a ROM. The storage device has a computer-readable storage medium such as a hard disk, and writes and reads information necessary for control. In the controller 4, the CPU controls the film forming apparatus 100 by executing a program such as a process recipe stored in the ROM or the storage medium of the storage device while using the RAM as a work area.

### <Film Forming Method>

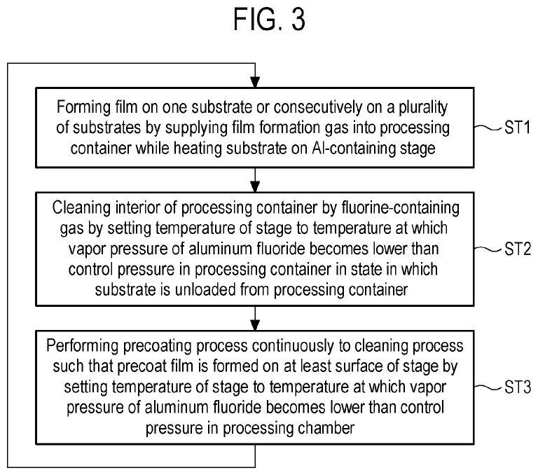

Next, a film forming method performed in the film forming apparatus 100 configured as described above will be described. FIG. 3 is a flowchart illustrating a film forming method according to an embodiment.

As illustrated in FIG. 3, in the present embodiment, step ST1, step ST2, and step ST3 are repeatedly performed. In step ST1, while heating the substrate W placed on the Al-containing stage 11, the film formation gas is supplied into the processing container 1 to form a film on one substrate W or consecutively on a plurality of substrates W. In step ST2, in a state in which the substrate W is unloaded from the processing container 1, a temperature of the stage 11 is set to a temperature at which a vapor pressure of aluminum fluoride becomes lower than a control pressure in the processing container 1 (i.e., a pressure in the processing container 1 set by controlling the gas supply mechanism 3 and/or the exhaust device 16 by the controller 4), and the interior of the processing container 1 is cleaned with a fluorine-containing gas. In step ST3, the temperature of the stage 11 is set to a temperature at which the vapor pressure of aluminum fluoride becomes lower than the control pressure in the processing container 1 as in step ST2, and continuously to the cleaning process, a precoating process is performed to form a precoat film on at least a surface of the stage 11.

In the film forming process of step ST1, film formation is performed on one substrate W or consecutively on a plurality of substrates W in a state in which the precoating process of step ST3 to be described later is performed in the processing container 1. Up to about 100 substrates W are exemplified as the plurality of substrates W. The film to be formed is not particularly limited, but a silicon (Si)-containing film, for example, a SiN film is exemplified as an appropriate example. Other Si-containing films such as a SiCN film, a SiO₂ film, and a SiON film may be formed.

When forming a SiN film, a Si-containing gas and a nitrogen-containing gas may be used as the film formation gas. As the Si-containing gas, for example, a silane-based compound gas such as monosilane (SiH₄) gas, disilane (Si₂H₆) gas, and trimethylsilane (SiH(CH₃)₃) gas may be used. In addition, as the nitrogen-containing gas, for example, ammonia (NH₃) gas, nitrogen (N₂) gas, or the like may be used. When forming a SiCN film, as the film formation gas, a gas obtained by adding a carbon-containing gas to the above-mentioned Si-containing gas and nitrogen-containing gas may be used. As the carbon-containing gas, a hydrocarbon-based gas such as ethylene (C₂H₄) gas, acetylene (C₂H₂) gas, ethane (C₂H₆) gas, propylene (C₃H₆) gas, or trimethylsilane ((CH₃)₃SiH) gas may be used. When forming a SiO₂ film, a Si-containing gas and an oxygen-containing gas may be used. As the Si-containing gas, the above-mentioned silane-based compound gas may be used. In addition, as the oxygen-containing gas, for example, oxygen (O₂) gas, nitric oxide (NO) gas, nitrous oxide (N₂O) gas, or the like may be used. When forming a SiON film, as the film formation gas, a gas obtained by adding the above-mentioned nitrogen-containing gas to the above-mentioned Si-containing gas and oxygen-containing gas may be used. In any cases, another gas, such as argon (Ar) gas or helium (He) gas, may be used as a dilution gas or a plasma generation gas.

The film to be formed is not limited to the Si-containing film, and may be, for example, a Ti-based film such as a Ti film or a TiN film, or a carbon film.

In the film forming process of step ST1, first, the gate valve 18 is opened, and a substrate W held on a transfer arm (not illustrated) is loaded into the processing container 1 from the load/unload port 17 and placed on the stage 11. Then, the gate valve 18 is closed. At this time, the stage 11 is heated by the heater 13, and a temperature of the substrate W on the stage 11 is controlled. When forming a SiN film as described above, it is desirable that the temperature of the substrate W is set to be 500 degrees C. or higher. Specifically, it is desirable that the temperature of the substrate W is set to be 500 degrees C. to 650 degrees C. Thereafter, the above-mentioned film formation gas according to the film to be formed is introduced into the processing container 1, the pressure in the processing container 1 is controlled, and the film forming process is performed by plasma chemical vapor disposition (CVD). The pressure in the processing container 1 may be arbitrarily selected depending on a distance from a plasma source to the substrate W, a manner in which plasma is diffused, a film formation rate, a thickness of the film to be formed, or the like. When the film to be formed is a SiN film, a pressure of 266 Pa or less may be used.

When generating plasma, the microwaves are output from the microwave output 30 of the plasma source 2 while introducing a gas into the processing container 1. At this time, the microwaves distributed and output from the microwave output 30 are amplified by the amplifiers 42 of the microwave transmitter 40 and then transmitted to the central microwave introducer 43a and the peripheral microwave introducers 43b. Thereafter, the transmitted microwaves penetrate the slow-wave members 121 and 131 of the microwave radiators 50, the slots 122 and 132 of the slot antennas 124 and 134, and the dielectric members 123 and 133 which are microwave transmission windows, and are radiated into the processing container 1. At this time, by moving the slugs 54, the impedance is automatically matched, and the microwaves are supplied in a state in which there is substantially no power reflection. The radiated microwaves propagate on the surface of the ceiling wall 20 as surface waves. The gas introduced into the processing container 1 is excited by electric fields of the microwaves, and surface wave plasma is formed in the plasma generation space U directly below the ceiling wall 20 in the processing container 1. Through plasma CVD by this surface wave plasma, a SiN film, for example, is formed on the substrate W.

In the film forming apparatus 100 of the present embodiment, since the substrate W is disposed in a region distanced from a plasma generation region and plasma diffused from the plasma generation region is supplied to the substrate W, the plasma is essentially high density plasma having a low electron temperature. Since the electron temperature of the plasma is controlled to be low, it is possible to perform film formation without damaging the formed film or elements of the substrate W, whereby a high-quality film can be obtained by high-density plasma. In addition, since the film quality is improved as a film formation temperature increases, when the film to be formed is a SiN film, a higher quality film can be formed by increasing the film formation temperature to 500 degrees C. or higher as described above.

After forming the film such as a SiN film as described above, the substrate W is unloaded from the processing container 1 and the film forming process of step ST1 ends.

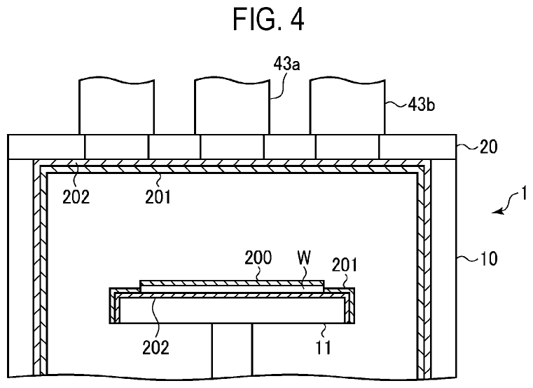

After the film forming process of step ST1 as described above, the cleaning process of step ST2 is carried out. As illustrated in FIG. 4, after the film forming process of step ST1, a deposit 201 having the same components as a precoat film 202 and a film 200 formed on the substrate W is deposited in the processing container 1. When a subsequent film formation is performed in such a state in which the deposit 201 is deposited, the deposit 201 causes particles and the like. Thus, a cleaning process of cleaning and removing the deposit 201 is performed.

The cleaning process of step ST2 is performed by a fluorine-containing gas. As the fluorine-containing gas, for example, radicals or ions of NF₃ gas excited by plasma may be used. The plasma at this time may be generated by using the plasma source 2 of the film forming apparatus 100, or may be generated by using another plasma source, for example, a remote plasma. The NF₃ gas is supplied from the gas supply mechanism 3 into the processing container 1. The NF₃ gas may be diluted with Ar gas or He gas. In addition, in order to adjust a cleaning speed, chlorine (Cl₂) gas, O₂ gas, N₂ gas, hydrogen bromide (HBr) gas, carbon tetrafluoride (CF₄) gas, or the like may be added. The NF₃ gas excited by the plasma may be appropriately used, for example, when the film to be formed on the substrate W is a Si-containing film such as a SiN film.

As the fluorine-containing gas used for cleaning, a gas other than the NF₃ gas, such as F₂ gas, CF-based gas, or ClF₃ gas, may be used. Such other fluorine-containing gases may not be excited by plasma, and may be diluted with Ar gas or He gas. In addition, another additive gas may be added to the fluorine-containing gas. The fluorine-containing gas may be selected depending on a material of a film adhering to and deposited in the processing container 1.

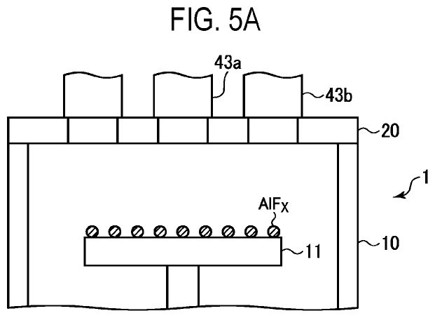

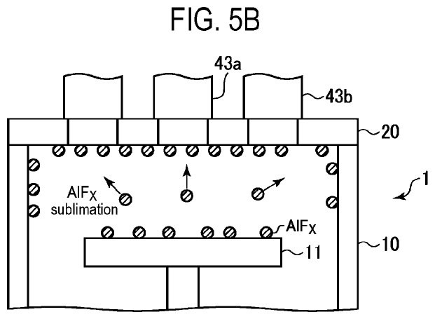

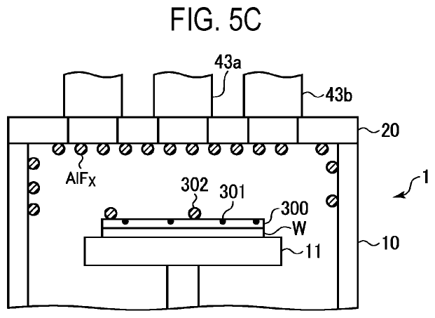

In the cleaning process, when the stage 11 is at a high temperature, the fluorine-containing gas used as the cleaning gas reacts with an Al-containing material such as AlN constituting the stage 11. As a result, as illustrated in FIG. 5A, an aluminum fluoride (AlFₓ) typified by aluminum trifluoride (AlF₃) is unintentionally generated on the surface of the stage 11. For example, when NF₃ gas excited by plasma is used, AlFₓ is generated at 150 degrees C. or higher due to very high reactivity. As the temperature increases, the fluorination reaction more easily proceeds, and a larger the amount of AlFₓ is generated. Since the interior of the processing container 1 is maintained to be a high vacuum, AlFₓ generated on the surface of the stage 11 is easily sublimated.

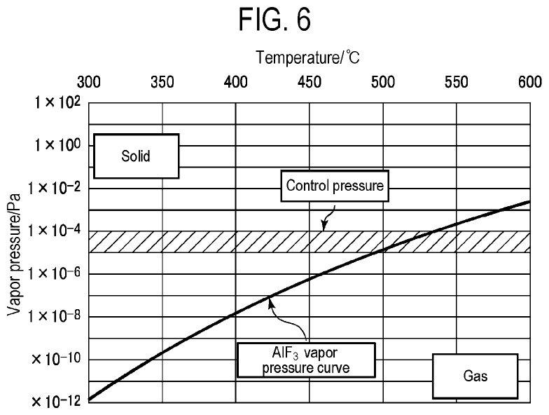

FIG. 6 is a theoretical vapor pressure curve of AlF₃, which is a typical aluminum fluoride. The vapor pressure has a correlation with a temperature, and AlF₃ becomes a solid state at a pressure above the vapor pressure curve and becomes a gaseous state at a pressure below the vapor pressure curve. As illustrated in FIG. 6, for example, at 600 degrees C., the vapor pressure of AlF₃ is 2.4×10⁻³ Pa, which is higher than a control pressure set in a vicinity of the ultimate vacuum degree in the processing container 1 for plasma CVD, and thus AlF₃ is easily sublimated. The sublimated AlFₓ diffuses from the surface of the stage 11, and as illustrated in FIG. 5B, adheres to and deposits on the inner wall of the processing container 1 having a low temperature, for example, the surface of the ceiling wall 20. When AlFₓ adheres to and deposits on the inner wall of the processing container 1, plasma state or the like changes, and thus it becomes difficult to perform stable and uniform film formation and a film thickness shifts. When the film forming process is performed in the state in which AlFₓ adheres to and deposits on the inner wall of the processing container 1, as illustrated in FIG. 5C, the AlFₓ is dissociated and mixed as a contaminant 301 into a film 300, which may deteriorate characteristics of the film 300 or cause defects. In addition, the AlFₓ is turned into particles 302 and falls in the film and on the film surface, which has an adverse effect.

Therefore, in the present embodiment, during the cleaning process of step ST2, the temperature of the stage 11 is lowered to suppress sublimation of aluminum fluoride (AlFₓ). More specifically, the temperature of the stage 11 is controlled to be a temperature at which the vapor pressure of AlFₓ becomes lower than the control pressure in the vicinity of the ultimate vacuum degree of the processing container 1. For example, in the case of AlF₃, the temperature of the stage 11 is controlled such that the control pressure in the vicinity of the ultimate vacuum degree in the processing container 1 becomes higher than the vapor pressure curve of AlF₃ in FIG. 6. In the case of a film forming process by plasma CVD as in the present embodiment, the ultimate vacuum degree is substantially 1×10⁻³ Pa to 1×10⁻⁴ Pa indicated by the oblique lines in FIG. 6, and when the pressure falls within this range, it is derived from FIG. 6 that sublimation of AlF₃ can be suppressed by setting the temperature of the stage 11 to 500 degrees C. or lower. It is desirable that the temperature of the stage 11 at this time is lower than the temperature of the stage 11 in the film forming process of step ST1. In addition, in order to effectively suppress sublimation of AlFₓ, it is advantageous that the vapor pressure of AlFₓ exists below the ultimate vacuum degree in the processing container 1. In consideration of this point, it is more desirable that the temperature of the stage 11 is set to be 450 degrees C. or lower.

Lowering the cleaning temperature also has an effect of reducing a reaction temperature of a fluoride reaction between AlN of the stage 11 and the fluorine-containing gas (NF₃ gas) as the cleaning gas. Thus, there is an effect that an amount of generated aluminum fluoride (AlFₓ) itself can also be reduced.

In the cleaning process of step ST2, basically, the pressure in the processing container 1 when supplying the cleaning gas and actually performing cleaning may be set arbitrary depending on a volume of the processing container 1, or a manner in which plasma used for cleaning is diffused when the plasma is used. The pressure is exemplified in a range of 10 Pa to 1,000 Pa, specifically, 400 Pa.

The precoating process of step ST3 is performed after the cleaning process of step ST2 and prior to a subsequent film forming process. In the precoating process, in a state in which the substrate W does not exist in the processing container 1, a precoat film including a film to be formed on the substrate W in the film forming process or components of the film is deposited on at least the surface of the stage 11 inside the processing container 1. At this time, the precoat film is also deposited on the surface of the side wall or the ceiling wall 20 of the processing container 1. As the precoat film, the same material as the film to be formed on the substrate W or a material containing the components of the film to be formed may be used. For example, when the film to be formed is a SiN film, the precoat film may be the same SiN film, or may be another Si-based film such as a SiCN film, a SiON film, or a SiOC film.

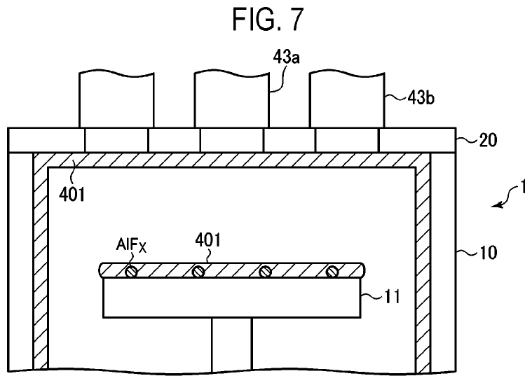

The precoating process of step ST3 is performed continuously to the cleaning process, while as in the cleaning process of step ST2, the temperature of the stage 11 is controlled to be a temperature at which the vapor pressure of aluminum fluoride (AlFₓ) becomes lower than the control pressure in the processing container 1. In addition, it is desirable that the temperature of the stage 11 in the precoating process of step ST3 is lower than the temperature of the stage 11 in the film forming process of step ST1 as in the case of the cleaning process. It is more desirable that the temperature of the stage 11 is set to 450 degrees C. or lower. In addition, it is furthermore desirable that the temperature of the stage 11 in the precoating process of step ST3 is the same as the temperature of the stage 11 in the cleaning process of step ST2. By lowering the temperature of the stage 11 and performing precoating as described above, it is possible to suppress sublimation of AlFₓ itself during the precoating process. In addition, by performing the precoating process continuously to the cleaning process, as illustrated in FIG. 7, even when the AlFₓ remains on the surface of the stage 11, it is possible to shield the AlFₓ by a precoat film 401. Since the AlFₓ on the surface of the stage 11 is shielded by the precoat film 401 as described above, it is possible to suppress sublimation of AlFₓ on the surface of the stage 11 during a temperature increase before ae subsequent film forming process and the subsequent film forming process at a high temperature. In addition, by coating the surface of the stage 11 with the precoat film, it is possible to prevent metallic contaminants from adhering to a rear surface of a substrate W during a transfer of the substrate W, which is a problem in a semiconductor manufacturing process.

Here, performing the precoating process “continuously” to the cleaning process means that the precoating process is performed promptly after the cleaning process without going through other processes. The precoating process may include a preprocess such as plasma processing performed before forming the precoat film 401.

It is desirable that the pressure inside the processing container 1 in the precoating process is set to be a low pressure of, for example, 100 Pa or less, so that the precoat film is formed preferentially on the surface of the stage 11.

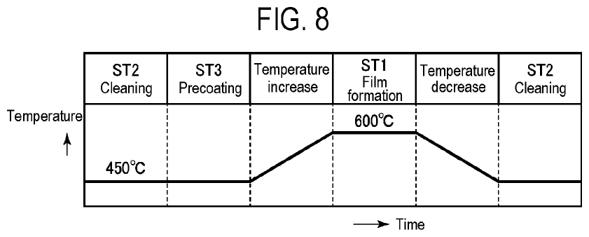

As described above, in the present embodiment, as shown in FIG. 8, the cleaning process of step ST2 and the precoating process of step ST3 are continuously performed at a low temperature, for example, 450 degrees C., and then the temperature of the stage 11 is increased to a high temperature of, for example, about 600 degrees C., to perform the film forming process of a subsequent step ST1. Then, after the film forming process, the temperature of the stage 11 is decreased to a low temperature of, for example, 450 degrees C., and a subsequent cleaning process is performed. When increasing and decreasing the temperature of the stage 11, since the precoat film is formed to shield AlFₓ on the surface of the stage 11, it is desirable that the temperature increase and decrease are controlled such that the precoat film is not peeled off.

Next, an experiment confirming an effect of the present embodiment will be described.

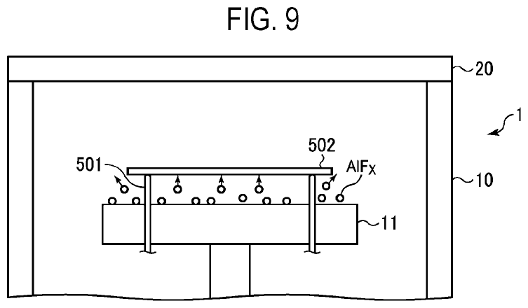

Here, amounts of Al contamination were measured for the following Samples A to C by a measurement method which will be illustrated below. Sample A is a sample that was cleaned at a high temperature (600 degrees C.) and then subjected to film formation at the same high temperature. Sample B is a sample that was cleaned at a low temperature (450 degrees C.) and then subjected to film formation at a high temperature. Sample C is a sample of the present embodiment that was continuously subjected to cleaning and precoating at a low temperature and then subjected to film formation at a high temperature. As the measurement method, as illustrated in FIG. 9, a sample substrate 502 was placed on lifting pins 501 protruding from the top surface of the stage 11, and AlFₓ sublimated from the stage 11 and adsorbed on a rear surface of the sample substrate 502 was measured as Al contamination by X-ray fluorescence analysis (XRF). As a result, in Sample A of the conventional method, the Al contamination amount was as high as 5.0×10¹⁵ (atoms/cm²) or more, and a sublimation amount of AlFₓ sublimated in the processing container 1 was large. On the other hand, in the case of Sample B in which only cleaning was performed at a low temperature, the Al contamination amount was only slightly decreased to 3.1×10¹⁵ (atoms/cm²). Thus, it was confirmed that the effect of suppressing sublimation of AlFₓ was not sufficient. In contrast, in Sample C in which the method of the present embodiment was used, the Al contamination amount was 1.0×10¹² (atoms/cm²), which is a lower limit of measurement of a fluorescence X-ray device, or less. Thus, it was confirmed that sublimation of AlFₓ is reliably suppressed.

Next, other embodiments will be described.

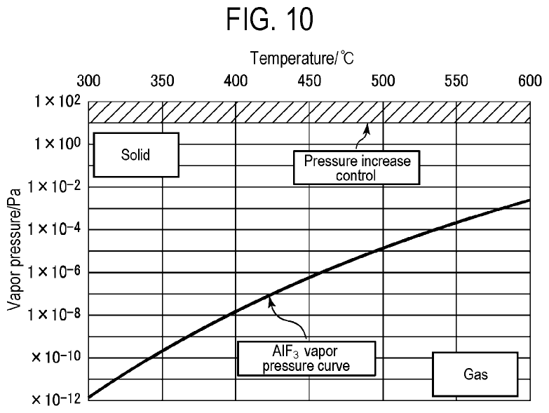

In the absence of a gas flow, the pressure in the processing container 1 is generally controlled to be a low pressure in the vicinity of the ultimate vacuum degree in order to control leaks and residual gas in the processing container 1. In addition, at the time of processing the substrate W, the pressure is controlled by adjusting a gas flow and an exhaust amount of an exhaust system. In such a pressure control, when the temperature of the stage 11 is increased as the process proceeds from the low-temperature precoating process toward the high-temperature film forming process, for example, the vapor pressure of AlFₓ may become higher than the low pressure in the vicinity of the ultimate vacuum degree, whereby sublimation of AlFₓ may occur. Therefore, in the present embodiment, when the temperature of the stage 11 is increased from the temperature in the precoating process to the temperature in the film forming process, an inert gas (Ar gas or N₂ gas) is flown to increase the control pressure in the processing container 1 as illustrate in FIG. 10 (pressure increase control). Thus, since the temperature of the stage 11 is increased while increasing the control pressure in the processing container 1 to be equal to or higher than the vapor pressure of AlFₓ, it is possible to further suppress sublimation of AlFₓ existing in a lower layer of the precoat film. That is, it is possible to further suppress sublimation of AlFₓ by performing the pressure increase control, in addition to shielding the AlFₓ by the precoat film.

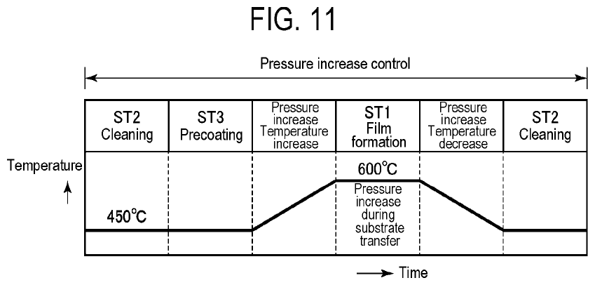

As shown in FIG. 11, by performing the pressure increase control not only during the temperature increase from the precoating process to the film forming process, but also during transferring the substrate W transfer in the film forming process performed at a high temperature and during a temperature decrease from the high-temperature film forming process to the low-temperature cleaning process, it is possible to further enhance the effect of suppressing sublimation of AlFₓ.

As a pressure in the pressure increase control, 266 Pa, for example, is used. In order to suppress sublimation of AlFₓ during the temperature increase and the like, it is desirable that the pressure in the pressure increase control is set such that a certain difference is obtained with respect to the vapor pressure of AlFₓ.

Next, another embodiment will be described.

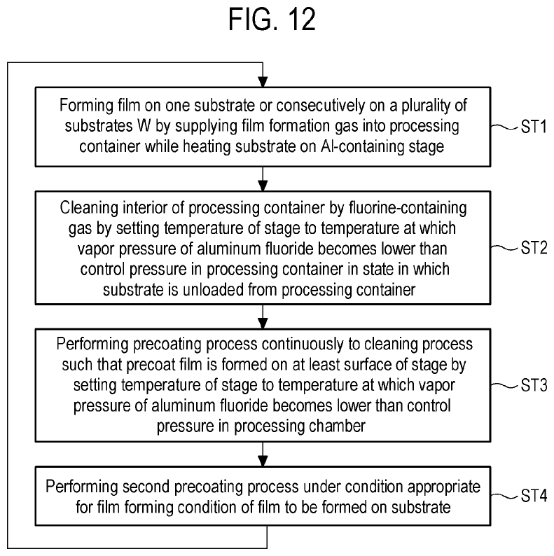

In the present embodiment, as illustrated in FIG. 12, after the precoating process of step ST3 described above, a second precoating process of step ST4 is performed under a condition appropriate for a film forming condition of a film to be formed on the substrate W.

The low-temperature precoating process of step ST3 is performed to shield AlFₓ on the stage 11 while suppressing sublimation of AlFₓ, and it is desirable that the precoating condition is set such that the precoating film is dense and has a high shielding effect due to the high film density. For example, when a SiN film is formed as a precoat film for forming a SiN film, it is desirable that the precoat film has a high RI value (refractive index) in order to obtain a high film density. The low-temperature precoating process of step ST3 is appropriate for forming a precoat film having such characteristics.

However, when forming a film on the substrate W, characteristics required for the film vary depending on various requirements on a semiconductor device. For example, when forming a SiN film on the substrate W, there is a requirement to form a SiN film having a low RI value or a requirement to control a stress value of the formed SiN film. Physical property values of a SiN film are determined by a film forming condition of the SiN film, but are also affected by a film quality of a precoat film. In order to form a SiN film having desired characteristics on the substrate W, it is also desirable that characteristics of the precoat film itself are close to those of the SiN film to be formed on the substrate W.

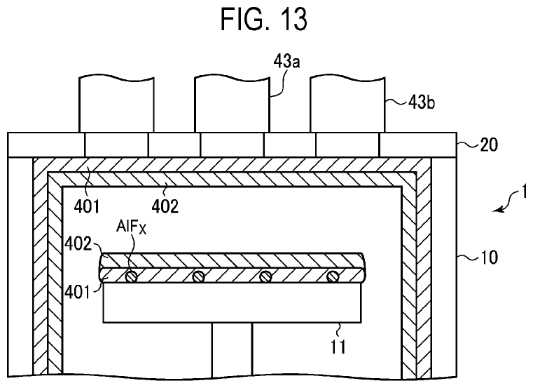

Therefore, in the present embodiment, after the low-temperature precoating process of step ST3, the second precoating process of step ST4 is performed under a condition appropriate for the film forming condition of the film to be formed on the substrate W. As a result, as illustrated in FIG. 13, on the first precoat film 401 formed on the surface of the stage 11 by the precoating process of step ST3, a second precoat film 402 is formed by the second precoating process of step ST4. The first precoat film 401 on a side of the stage 11 is formed under a low temperature and high density condition to shield AlFₓ, and after increasing the temperature to that in a subsequent film forming process, the second precoat film 402 on a side the surface is formed under the same or close condition to the film forming condition in the film formation on the substrate W in order to adjust the physical property values of the film to be formed on the substrate W. By multi-layering the precoating as described above, it is possible to achieve both suppressing sublimation of AlFₓ and controlling the film quality of the film to be formed on the substrate W.

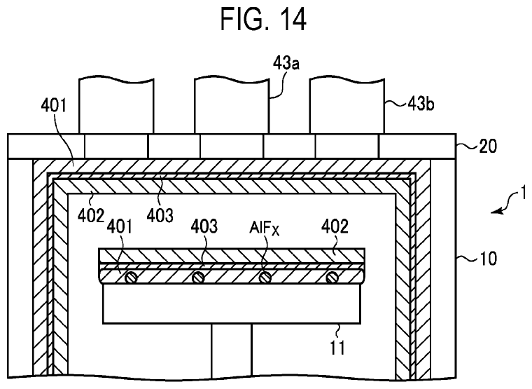

In addition, as illustrated in FIG. 14, an intermediate precoat film 403 may be formed between the first precoat film 401 formed by the precoating process of step ST3 and the second precoat film 402 formed by the second precoating process of step ST4. The intermediate precoat film 403 is used for the purpose of improving adhesion between the precoat films 401 and 402 by adjusting a stress between the first precoat film 401 and the second precoat film 402. With such a structure, it is possible to prevent the precoat films from being peeled off, thereby leading to reduction of particles and the like.

### <Other Applications>

Although embodiments have been described above, it should be considered that the embodiments disclosed herein are exemplary in all respect and are not restrictive. The above embodiments may be omitted, replaced, or modified in various forms without departing from the scope and gist of the appended claims.

For example, in the above-described embodiments, as a film forming apparatus for performing a film forming process, an apparatus that forms a film by using surface wave plasma generated by radiating microwaves from a plurality of microwave introducers into a processing container has been exemplified, but the present disclosure is not limited thereto. The number of microwave introducers may be one, and the plasma processing is not limited to radiating microwaves for generating plasma. For example, various other plasmas, such as capacitively coupled plasma (CCP), inductively coupled plasma (ICP), and electron cyclotron resonance (ECR) plasma, may be used. The film forming apparatus may be a thermal CVD apparatus or the like that does not use plasma.

In the above-described embodiments, a Si-containing film such as a SiN film is mainly exemplified as a film to be formed, but the present disclosure is not limited thereto. As described above, another film such as a Ti-based film or a carbon film may be formed. In addition, in the above-described embodiments, an example in which NF₃ gas is excited by plasma as a cleaning gas has been illustrated, but as described above, another fluorine-containing gas such as F₂ gas, CF-based gas, or ClF₃ gas may also be used. An appropriate cleaning gas may be used depending on a film to be formed. For example, in a case of a Si-containing gas such as SiN, NF₃ gas excited by plasma may be appropriately used, in a case of a Ti-based film, F₂ gas or ClF₃ gas may be appropriately used, and in a case of a carbon film, a CF-based gas such as CF₄ gas may be appropriately used.

The present disclosure provides a film forming method and a film forming apparatus that are capable of suppressing an influence of an aluminum fluoride, which is generated by a reaction between a fluorine-containing gas as a cleaning gas and an aluminum-containing stage when an interior of a processing container is cleaned with the fluorine-containing gas after a film forming process, on film formation.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method of forming a film on a substrate by using a film forming apparatus including a processing container and an aluminum-containing stage on which the substrate is placed in the processing container, the film forming method comprising:
forming the film on one substrate or consecutively on a plurality of substrates by supplying a film formation gas into the processing container while heating the substrate on the stage;
cleaning an interior of the processing container by a fluorine-containing gas by setting a temperature of the stage to a first temperature at which a vapor pressure of an aluminum fluoride becomes lower than a control pressure in the processing container in a state in which the substrate is unloaded from the processing container; and
performing a precoating continuously to the cleaning the interior of the processing container such that a precoat film is formed on at least a surface of the stage by setting the temperature of the stage to a second temperature at which the vapor pressure of the aluminum fluoride becomes lower than the control pressure in the processing container,
wherein the forming the film, the cleaning the interior of the processing container, and the performing the precoating are repeatedly performed.

2. The film forming method of claim 1, wherein the forming the film is performed by setting the temperature of the stage to be 500 degrees C. or higher.

3. The film forming method of claim 1, wherein, the forming the film includes forming a Si-containing film.

4. The film forming method of claim 3, wherein the Si-containing film is a SiN film.

5. The film forming method of claim 1, wherein the forming the film is performed by generating plasma of the film formation gas.

6. The film forming method of claim 5, wherein the plasma is microwave plasma.

7. The film forming method of claim 1, wherein the cleaning the interior of the processing container includes using NF₃ gas excited by plasma as the fluorine-containing gas.

8. The film forming method of claim 1, wherein the precoat film formed in the performing the precoating is made of the same material as the film to be formed on the substrate, or contains a component of the film to be formed on the substrate.

9. A film forming method of forming a film on a substrate by using a film forming apparatus including a processing container and an aluminum-containing stage on which the substrate is placed in the processing container, the film forming method comprising:
forming a SiN film on one substrate or consecutively on a plurality of substrates by placing the substrate on the stage, supplying a Si-containing gas and a nitrogen-containing gas into the processing container while heating the substrate to be 500 degrees C. or higher, and generating plasma of the Si-containing gas and the nitrogen-containing gas;
cleaning an interior of the processing container by NF₃ gas exited by plasma, as a fluorine-containing gas, by setting a temperature of the stage to a first temperature at which a vapor pressure of an aluminum fluoride becomes lower than a control pressure in the processing container in a state in which the substrate is unloaded from the processing container; and
performing a precoating continuously to the cleaning the interior of the processing container such that a precoat film is formed on at least a surface of the stage by setting the temperature of the stage to a second temperature at which the vapor pressure of the aluminum fluoride becomes lower than the control pressure in the processing container,
wherein the forming the film, the cleaning the interior of the processing container, and the performing the precoating are repeatedly performed.

10. The film forming method of claim 9, wherein the plasma in the forming the film is microwave plasma.

11. The film forming method of claim 9, wherein the precoat film formed in the performing the precoating is a SiN film, which is identical to that formed on the substrate in the forming the SiN film, or another Si-based film.

12. The film forming method of claim 1, wherein the first temperature of the stage in the cleaning the interior of the processing container and the second temperature of the stage in the performing the precoating are equal to each other.

13. The film forming method of claim 1, wherein, the first temperature of the stage in the cleaning the interior of the processing container and the second temperature of the stage in the performing the precoating are equal to or lower than a temperature of the stage in the forming the film.

14. The film forming method of claim 13, wherein the first temperature of the stage in the cleaning the interior of the processing container and the second temperature of the stage in the performing the precoating are 450 degrees C. or lower.

15. The film forming method of claim 13, wherein, when the forming the film is performed continuously to the performing the precoating, the temperature of the stage is increased and at that time, an inert gas is introduced into the processing container to increase the control pressure.

16. The film forming method of claim 1, further comprising, after the performing the precoating, performing a second precoating under a condition appropriate for a film forming condition of the film to be formed on the substrate.

17. The film forming method of claim 16, wherein a temperature of the stage in the performing the second precoating is equal to a temperature of the stage in the forming the film.

18. The film forming method of claim 1, wherein the stage is made of an aluminum nitride.

19. A film forming apparatus comprising:
a processing container;
an aluminum-containing stage provided in the processing container and configured to place a substrate thereon;
a heater configured to heat the stage;
a gas supply configured to supply a gas into the processing container; and
a controller,
wherein the controller is configured to perform a control to repeatedly perform:
forming a film on one substrate or consecutively on a plurality of substrates by supplying a film formation gas into the processing container while heating the substrate on the stage;
cleaning an interior of the processing container by a fluorine-containing gas by setting a temperature of the stage to a first temperature at which a vapor pressure of an aluminum fluoride becomes lower than a control pressure in the processing container in a state in which the substrate is unloaded from the processing container; and
performing a precoating continuously to the cleaning the interior of the processing container such that a precoat film is formed on at least a surface of the stage by setting the temperature of the stage to a second temperature at which the vapor pressure of the aluminum fluoride becomes lower than the control pressure in the processing container.

20. The film forming apparatus of claim 19, further comprising a plasma source configured to generate plasma of the film formation gas.

21. The film forming apparatus of claim 20, wherein the plasma source is configured to generate microwave plasma.
